(19) United States
(12) Patent Application Publication
(10) Pub. No.: US 2026/0107408 A1
(43) Pub. Date: Apr. 16, 2026

(54) SERVER COOLING SYSTEM WITH WIRE-GUIDANCE PATHWAY AND ELECTROMAGNETIC INTERFERENCE (EMI) SUPPRESSION

(71) Applicant: Quanta Computer Inc., Taoyuan City (TW)

(72) Inventor: Ching-Jen CHEN, Taoyuan City (TW)

(21) Appl. No.: 18/911,645

(22) Filed: Oct. 10, 2024

(51) Int. Cl. H05K 7/14; H05K 7/20; H05K 9/00

(52) U.S. Cl. CPC H05K 7/1491; H05K 7/20145; H05K 7/20727; H05K 9/0081

(57) ABSTRACT

A server system includes a server chassis with heat-generating electronic components. A cooling system is mounted on the server chassis and provides cooling air to the heat-generating electronic components. A ventilation channel is disposed on the server chassis between the cooling system and the heat-generating electronic components. The ventilation channel includes a cooling path along which the cooling air flows. The cooling path is formed at least in part between two sidewalls and a cover plate. The ventilation channel further includes a wire path configured to receive a wire. The wire path is formed in part as a slotted region that is recessed within the cover plate.

### FIELD OF THE INVENTION

The present invention relates generally to a cooling system for a server, and more specifically, to a cooling system that efficiently guides air across one or more heat exchangers, while also providing an integrated pathway to manage an arrangement of wires and cables that link the various electronic components and suppressing electromagnetic interference (EMI) caused thereby.

### BACKGROUND OF THE INVENTION

Server products are composed of diverse electronic devices that are installed within a server chassis. As memory, such as dual in-line memory modules, processors, and other components expand, power consumption also rises, resulting in the production of more waste heat. Furthermore, the physical space inside the server chassis is restricted, providing only a limited amount of room for fans, air ducts, and cables/wires that link the electronic components. Packing the electronic components closely together can result in electromagnetic interference (EMI) caused by a coupling of electromagnetic fields produced by wires and cables in close proximity to processors and/or memory. There is a need for a server cooling system that can effectively dissipate heat, while also managing the arrangement of wires and cables that link the different electronic components and mitigating EMI caused by the wires and cables.

### SUMMARY OF THE INVENTION

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

According to certain aspects of the present disclosure, a server system includes a server chassis with heat-generating electronic components. A cooling system is mounted on the server chassis and provides cooling air to the heat-generating electronic components. A ventilation channel is disposed on the server chassis between the cooling system and the heat-generating electronic components. The ventilation channel includes a cooling path along which the cooling air flows. The cooling path is formed at least in part between two sidewalls and a cover plate. The ventilation channel further includes a wire path configured to receive a wire. The wire path is formed in part as a slotted region that is recessed within the cover plate.

According to certain aspects of the present disclosure, the slotted region has a depth that extends from a top end of at least one sidewall. The depth extends only partially through a height of the at least one sidewall.

According to certain aspects of the present disclosure, the top end is adjacent to the cover plate.

According to certain aspects of the present disclosure, the slotted region has a length that extends generally parallel to the cover plate.

According to certain aspects of the present disclosure, the server system further includes the wire and electromagnetic interference (EMI) absorbent material disposed around the wire.

According to certain aspects of the present disclosure, the EMI absorbent material at least partially seals against the slotted region to inhibit air flow through the wire path.

According to certain aspects of the present disclosure, the server system further includes a layer of electromagnetic interference (EMI) absorbent material disposed on at least one of the two sidewalls.

According to certain aspects of the present disclosure, the server system further includes one or more clamping structures configured to retain the wire within the wire path.

According to certain aspects of the present disclosure, the cooling system includes a plurality of cooling fans. The cover plate includes a plurality of cutouts. Each cutout is configured to accommodate a respective cooling fan of the plurality of cooling fans.

According to certain aspects of the present disclosure, each cutout is in sealed attachment with the respective cooling fan.

According to certain aspects of the present disclosure, a server system includes a ventilation channel having a cover plate and sidewalls depending from the cover plate. The ventilation channel is configured to attach to a chassis of the server to form at least a partially sealed path for air flowing from an inlet end of the ventilation channel to an outlet end of the ventilation channel. A heat exchanger is disposed within the ventilation channel. One or more metal tubes extend from the heat exchanger. The one or more metal tubes are configured to be in thermal contact with one or more heat-generating electronic components.

According to certain aspects of the present disclosure, the one or more metal tubes at least partially extend through the ventilation channel.

According to certain aspects of the present disclosure, the server system further includes a wire path recessed into the cover plate and extending from the inlet end to the outlet end of the ventilation channel. The wire path is configured to accommodate a wire.

According to certain aspects of the present disclosure, the server system further includes electromagnetic interference (EMI) absorbent material configured to be disposed around the wire disposed in the wire path. The EMI absorbent material at least partially forms a seal inside the wire path to inhibit air flow through the wire path.

According to certain aspects of the present disclosure, the cover plate includes a cutout disposed through the cover plate at the inlet end. The cutout is configured to seal the inlet end of the ventilation channel to a fan.

According to certain aspects of the present disclosure, a server system includes a ventilation channel having a cover plate and sidewalls depending from the cover plate. The ventilation channel is configured to attach to a chassis of the server to form at least a partially sealed path for air flowing from an inlet end of the ventilation channel to an outlet end of the ventilation channel. A heat exchanger is disposed within the ventilation channel. A wire path is recessed into the cover plate and extends from the inlet end to the outlet end of the ventilation channel. The wire path is configured to accommodate a wire.

According to certain aspects of the present disclosure, the server system further includes one or more metal tubes extending from the heat exchanger. The one or more metal tubes are configured to be in thermal contact with one or more heat-generating electronic components.

According to certain aspects of the present disclosure, the server system further includes electromagnetic interference (EMI) absorbent material configured to be disposed around the wire disposed in the wire path. The EMI absorbent material at least partially forms a seal inside the wire path to inhibit air flow through the wire path.

According to certain aspects of the present disclosure, the cover plate includes a cutout disposed through the cover plate at the inlet end. The cutout is configured to seal the inlet end of the ventilation channel to a fan.

According to certain aspects of the present disclosure, the heat exchanger includes a plurality of fins arranged to extend along a direction of air flow through the ventilation channel.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure, and its advantages and drawings, will be better understood from the following description of representative embodiments together with reference to the accompanying drawings. These drawings depict only representative embodiments, and are therefore not to be considered as limitations on the scope of the various embodiments or claims.

FIG. 1 is a schematic perspective view of a server having a chassis that contains printed circuit boards and electronics modules, according to certain aspects of the present disclosure.

FIG. 2 is a schematic perspective view of two ventilation channels, according to certain aspects of the present disclosure.

FIG. 3A is a schematic top plan view of two ventilation channels, according to certain aspects of the present disclosure.

FIG. 3B is a schematic elevational view of a ventilation channel, according to certain aspects of the present disclosure.

FIG. 4 is an enlarged schematic perspective view of the region of FIG. 1 denoted by the dashed ellipse labeled A and shown enlarged with the cover plate made transparent, according to certain aspects of the present disclosure.

FIG. 5 is a schematic perspective view of tabs extending from a side of a server chassis for attachment of a ventilation channel thereto, according to certain aspects of the present disclosure.

### DETAILED DESCRIPTION

The current invention is a cooling system for a server. The cooling system efficiently cools heat-generating electronic components in the server chassis. The cooling system also provides a wire path for management of wires and suppression of electromagnetic interference (EMI) caused by close proximity of the wires to other components within the server chassis.

Various embodiments are described with reference to the attached figures, where like reference numerals are used throughout the figures to designate similar or equivalent elements. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

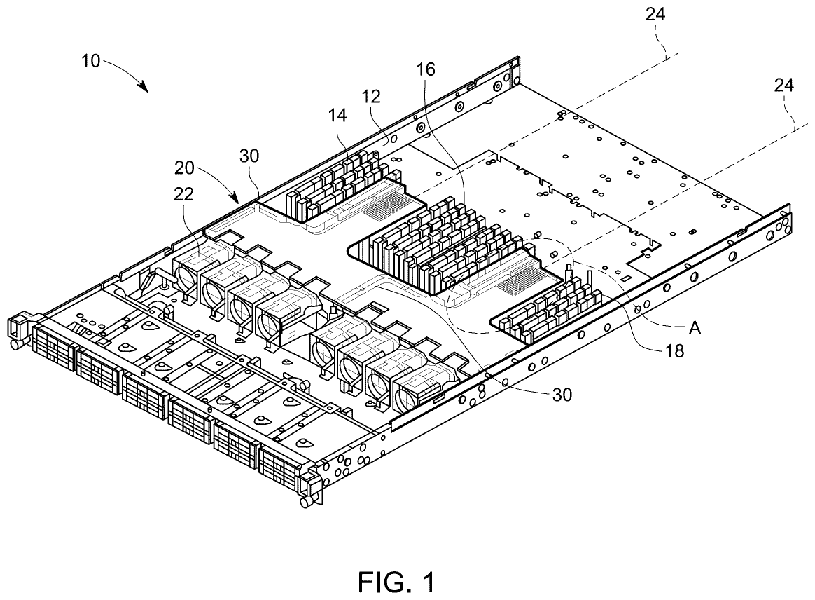

Referring to FIG. 1, a server 10 is schematically illustrated. The server 10 includes a server chassis 12 with heat-generating electronic components. The heat-generating electronic components include printed circuit boards (PCBs) including, for example, electronics modules 14, 16, 18 located in the middle region of the server chassis 12. In an embodiment, the electronics modules 14, 16, 18 are dual in-line memory modules (DIMMs). A cooling system is mounted on the server chassis 12 and provides cooling air to the heat-generating electronic components. In an embodiment, the cooling system includes a plurality of cooling fans 22.

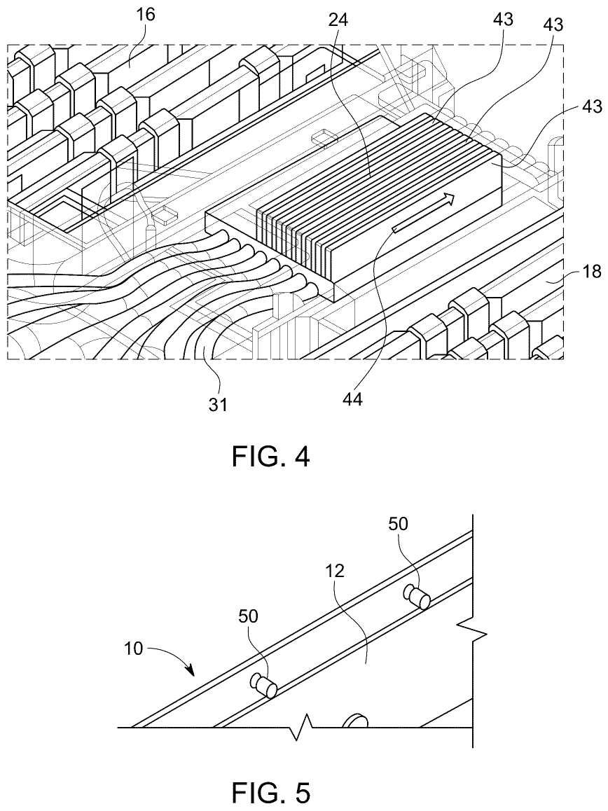

In an embodiment, at least one ventilation channel 20 is disposed on the server chassis 12 between the plurality of cooling fans 22 and the heat-generating electronic components. Each ventilation channel 20 guides air from the plurality of cooling fans 22 across one or more heat exchangers 24. The heat exchangers 24 are in thermal contact with the heat-generating components. Thermal contact is established by locating each heat exchanger in direct contact with a heat-generating component, for example directly on top of the heat-generating component. Alternatively or in addition, thermal contact is established through one or more metal tubes (e.g., copper tubes) 31 (see FIG. 4) that extend from the heat exchanger 24 to contact the heat-generating component. Waste heat is transferred from the heat-generating components to the heat exchangers 24 by thermal conduction. The waste heat is removed from the heat exchangers 24 by thermal convection into the cooling air.

FIG. 1 illustrates two ventilation channels 20 disposed side-by-side guiding air from the plurality of cooling fans 22, separated into two groups, across two heat exchangers 24. Although the heat exchangers 24 are shown to be visible for clarity of location in FIG. 1, the heat exchangers 24 are actually disposed entirely within the ventilation channels 20. Although a single heat exchanger 24 is shown in FIG. 1, there can be two or more heat exchangers 24 in each ventilation channel 20.

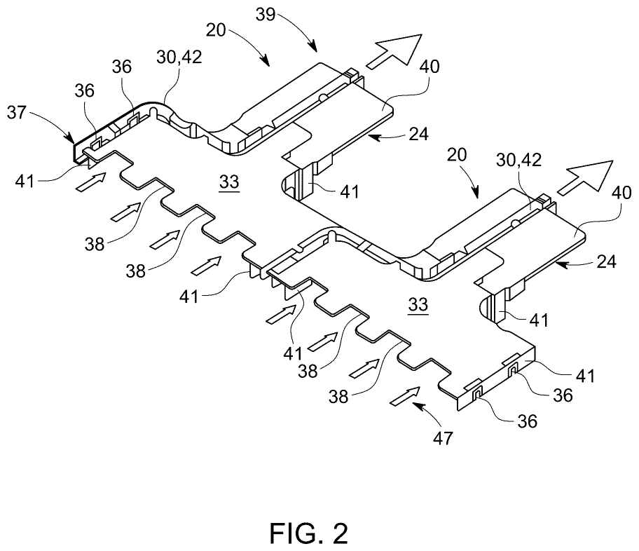

Referring to FIG. 2, two ventilation channels 20 are shown in a schematic perspective view. The two ventilation channels 20 can be formed as a single unitary structure having two channels and spanning a width of the server chassis 12 (FIG. 1), or as two or more separate ventilation channels 20. In an embodiment, each ventilation channel 20 includes a cover plate 33. Each ventilation channel 20 provides a cooling path along which the cooling air flows, from an inlet end 37 to an outlet end 39. The cooling path is formed at least in part between the cover plate 33 and two sidewalls 41 depending from the cover plate 33. The one or more exchangers 24 are not directly visible in FIG. 2, but are disposed within each of the ventilation channels 20, as indicated by arrows labeled 24.

In an embodiment, the cover plate 33 includes a plurality of cutouts 38. Each of the cutouts 38 is configured to accommodate a respective cooling fan 22 of the plurality of cooling fans 22. In an embodiment, each of the cutouts 38 is in sealed attachment with a respective cooling fan 22 of the plurality of cooling fans 22. In an embodiment, the ventilation channel 20 is therefore configured to form at least a partially sealed path for air flowing from the inlet end 37 of the ventilation channel 20 to the outlet end 39 of the ventilation channel 20.

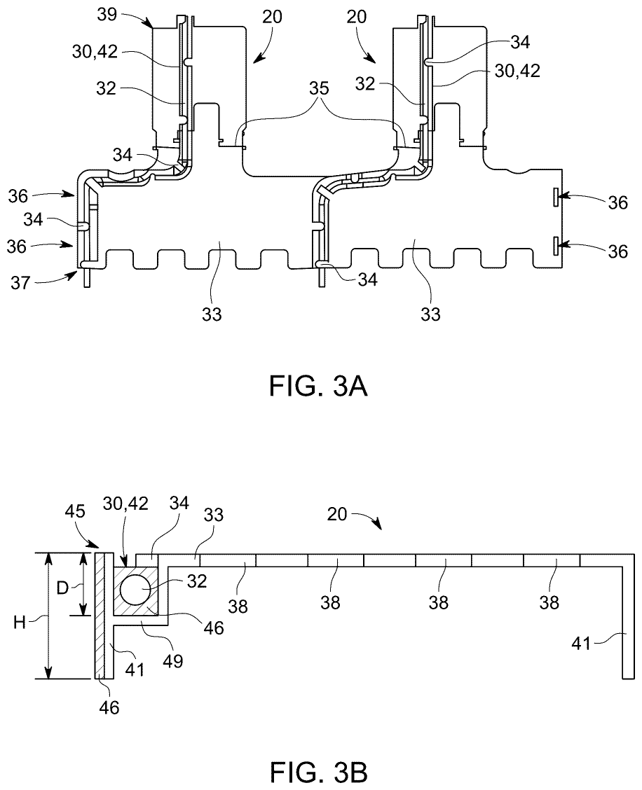

Still referring to FIG. 2, the flow of the air from the plurality of cooling fans 22 (FIG. 1) into each ventilation channel 20 is depicted by a series of arrows 47. The arrows 47 indicate a flow of cooling air from each of the cooling fans 22 flowing into the inlet end 37 of each ventilation channel 20 below the cover plate 33. Each of the arrows 47 schematically corresponds to a single fan 22 such that an upper surface of the fan 22 fits within cutout 38, as described above. The cooling air exits the ventilation channels 20 at outlets 40 (as indicated by the large arrows shown in relation to the outlets 40). After exiting the ventilation channels 20 at the outlets 40, the cooling air continues to circulate over the server chassis 12 (FIG. 1) to provide further cooling of other electronic components before ultimately exiting the server 10 (FIG. 1) through vents in the server chassis 12. Arrows 48 are illustrated as being crossed out with a large X. This symbology is indicative of an inhibited flow of cooling air flowing into the wire paths 30, which is further explained in regard to FIG. 3B below.

Referring to FIG. 3A, two ventilation channels 20 are shown in a schematic plan view. In an embodiment, each of the ventilation channels 20 includes a wire path 30 configured to receive a wire 32. In an embodiment, the wire path 30 is recessed within the cover plate 33 or is formed in part as a slotted region 42 that is recessed within the cover plate 33. In an embodiment, the slotted region 42 has a solid bottom surface 49 as shown in FIG. 3B. In other embodiments the bottom surface 49 of the slotted region 42 can have one or more openings due to manufacturing processes or other reasons. If such openings result in a loss of cooling airflow therethrough, the openings can be covered with a layer of material, for example, an adhesive tape or strip of plastic.

In an embodiment, the wire path 30 extends from the inlet end 37 to the outlet end 39 of the ventilation channel 20. In an embodiment, one or more clamping structures 34 are configured to retain the wire 32 within the wire path 30. The clamping structures 34 can be, for example, bendable wire strips or tabs that can be simply pushed into place over the wire 32. In an embodiment, each of the ventilation channels 20, or a unitary ventilation channel 20 having two or more channels, is separatable into multiple individual parts along a seam 35. The seam 35 allows one or all of the multiple individual parts to be removed and reinstalled on the server chassis 12 independently.

Referring to FIG. 3B, the slotted region 42 has a depth D that extends from a top end 45 of at least one sidewall 41, the top end 45 being the end closest to the cover plate 33. In an embodiment the depth D extends only partially through a height H of the at least one sidewall 41. In an embodiment, the slotted region 42 extends lengthwise in a direction that is generally parallel to the cover plate 33. A wire (or cable) 32 is shown disposed within the wire path or slotted region 30, 42.

In an embodiment, an electromagnetic interference (EMI) absorbent material 46 is shown surrounding the wire 32. In an embodiment, the EMI absorbent material 46 is a sheet of material that wraps around the wire 32. In another embodiment, the EMI absorbent material 46 is potted into the slotted region 42 around the wire 32. Regardless of the form of the EMI absorbent material 46, in an embodiment, the EMI absorbent material 46 at least partially seals the wire 32 against the slotted region 42 to inhibit air flow and suppress air leakage through the wire path 30. In an embodiment, a layer of EMI absorbent material 46 is disposed on at least one of the two sidewalls 46.

Referring to FIG. 4, the region of FIG. 1 denoted by the dashed ellipse labeled A is shown enlarged with the cover plate 33 (FIGS. 2-3B) made transparent. As noted above, one or a plurality of heat exchangers 24 is disposed within each ventilation channel 20 (FIGS. 1-3B). Each heat exchanger 24 includes a plurality of fins 43 arranged to extend along a direction of air flow 44 through the ventilation channel 20. In an embodiment, the heat exchanger 24 or one or more of the plurality of heat exchangers 24 is disposed in direct thermal contact with a top of a respective heat-generating electronic component. Heat from the heat-generating electronic component conducts through the respective heat exchanger 24 into the plurality of fins 43 that are disposed in the cooling air flow through the ventilation channel 20.

In another embodiment, the heat exchanger 24 or one or more of the plurality of heat exchangers 24 is not disposed on top of a heat-generating electronic component. In this embodiment, one or more metal tubes 31 (e.g., copper tubes) extend from the heat exchanger 24. The one or more metal tubes 31 are configured to be in thermal contact with one or more of the heat-generating electronic components. Each heat exchanger 24 receives heat from a heat-generating electronic component via the one or more conductive metal tubes 31. In an embodiment, the one or more metal tubes 31 at least partially extend through the ventilation channel 20 and act as heat-exchanging surfaces that release waste heat into the moving air flowing through the ventilation channel 20.

Referring in general to FIGS. 2 and 5, the ventilation channel 20 is attached to the server chassis 12 via one or more slots 36. The one or more slots 36 attach over one or more respective tabs or extensions 50 that extend from a side of the server chassis 12. Referring in particular to FIG. 2, one or more slots 36 is positioned in each of the sidewalls 41. The slots 36 are disposed at mounting regions of each of the sidewalls 41. Referring in particular to FIG. 5, the slots 36 cooperate with the tabs or extensions 50 on the server chassis 12, for example, by snapping or pressing onto them, to attach the ventilation channel 20 to the server chassis 12. Embodiments having two or more of the ventilation channels 20 have the slots 36 in each of the sidewalls 41 of each of the ventilation channels 20. Such embodiments also have corresponding tabs or extensions 50 extending from a side of the server chassis 12 and distributed across a bottom of the server chassis 12 to receive the slots 36.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above described embodiments. Rather, the scope of the disclosure should be defined in accordance with the following claims and their equivalents.

What is claimed is:

1. A server system comprising:
a server chassis with heat-generating electronic components;
a cooling system mounted on the server chassis and providing cooling air to the heat-generating electronic components; and
a ventilation channel disposed on the server chassis between the cooling system and the heat-generating electronic components, the ventilation channel including
a cooling path along which the cooling air flows, the cooling path being formed at least in part between two sidewalls and a cover plate, and
a wire path configured to receive a wire, the wire path being formed in part as a slotted region that is recessed within the cover plate.

2. The server system of claim 1, wherein the slotted region has a depth that extends from a top end of at least one sidewall, the depth extending only partially through a height of the at least one sidewall.

3. The server system of claim 2, wherein the top end is adjacent to the cover plate.

4. The server system of claim 1, wherein the slotted region has a length that extends generally parallel to the cover plate.

5. The server system of claim 1, further comprising the wire and including electromagnetic interference (EMI) absorbent material disposed around the wire.

6. The server system of claim 5, wherein the EMI absorbent material at least partially seals against the slotted region to inhibit air flow through the wire path.

7. The server system of claim 1, further comprising a layer of electromagnetic interference (EMI) absorbent material disposed on at least one of the two sidewalls.

8. The server system of claim 1, further comprising one or more clamping structures configured to retain the wire within the wire path.

9. The server system of claim 1, wherein the cooling system includes a plurality of cooling fans, the cover plate including a plurality of cutouts, each cutout configured to accommodate a respective cooling fan of the plurality of cooling fans.

10. The server system of claim 9, wherein each cutout is in sealed attachment with the respective cooling fan.

11. A server system, comprising:
a ventilation channel having a cover plate and sidewalls depending from the cover plate, the ventilation channel configured to attach to a chassis of the server to form at least a partially sealed path for air flowing from an inlet end of the ventilation channel to an outlet end of the ventilation channel;
a heat exchanger disposed within the ventilation channel; and
one or more metal tubes extending from the heat exchanger, the one or more metal tubes configured to be in thermal contact with one or more heat-generating electronic components.

12. The server system of claim 11, wherein the one or more metal tubes at least partially extend through the ventilation channel.

13. The server system of claim 11, further comprising a wire path recessed into the cover plate and extending from the inlet end to the outlet end of the ventilation channel, the wire path configured to accommodate a wire.

14. The server system of claim 13, further comprising electromagnetic interference (EMI) absorbent material configured to be disposed around the wire disposed in the wire path, wherein the EMI absorbent material at least partially forms a seal inside the wire path to inhibit air flow through the wire path.

15. The server system of claim 11, wherein the cover plate includes a cutout disposed through the cover plate at the inlet end, the cutout configured to seal the inlet end of the ventilation channel to a fan.

16. A server system, comprising:
a ventilation channel having a cover plate and sidewalls depending from the cover plate, the ventilation channel configured to attach to a chassis of the server to form at least a partially sealed path for air flowing from an inlet end of the ventilation channel to an outlet end of the ventilation channel;
a heat exchanger disposed within the ventilation channel; and
a wire path recessed into the cover plate and extending from the inlet end to the outlet end of the ventilation channel, the wire path configured to accommodate a wire.

17. The server system of claim 16, further comprising one or more metal tubes extending from the heat exchanger, the one or more metal tubes configured to be in thermal contact with one or more heat-generating electronic components.

18. The server system of claim 16, further comprising electromagnetic interference (EMI) absorbent material configured to be disposed around the wire disposed in the wire path, wherein the EMI absorbent material at least partially forms a seal inside the wire path to inhibit air flow through the wire path.

19. The server system of claim 16, wherein the cover plate includes a cutout disposed through the cover plate at the inlet end, the cutout configured to seal the inlet end of the ventilation channel to a fan.

20. The server system of claim 16, wherein the heat exchanger includes a plurality of fins arranged to extend along a direction of air flow through the ventilation channel.
